(19) United States
(12) Patent Application Publication
(10) Pub. No.: US 2010/0155684 A1
(43) Pub. Date: Jun. 24, 2010

(54) NON-VOLATILE MEMORY DEVICE AND METHOD OF FORMING THE SAME

(75) Inventors: Sung-Yool CHOI, Daejeon (KR); Hu-Young Jeong, Daejeon (KR); In-Kyu You, Daejeon (KR); Kyoung-Ik Cho, Daejeon (KR)

Correspondence Address: RABIN & Berdo, PC, 1101 14TH STREET, NW, SUITE 500, WASHINGTON, DC, 20005, US

(73) Assignee: ELECTRONICS AND TELECOMMUNICATIONS RESEARCH INSTITUTE, Deajeon (KR)

(21) Appl. No.: 12/479,640

(22) Filed: Jun. 5, 2009

(30) Foreign Application Priority Data
Dec. 22, 2008 (KR) 10-2008-0130956

(51) Int. Cl. H01L 47/00; H01L 21/20; H01L 29/12

(52) U.S. Cl. 257/2; 438/514; 257/43; 257/E47.001; 257/E29.068; 257/E21.09

(57) ABSTRACT

Provided are a non-volatile memory device and a method of forming the non-volatile memory device. The non-volatile memory device includes a substrate, a lower electrode on the substrate, a diffusion barrier preventing the diffusion of a space charge on the lower electrode, a charge storage layer having a space charge limited characteristic on the diffusion barrier, and an upper electrode on the charge storage layer.

### CROSS-REFERENCE TO RELATED APPLICATIONS

This U.S. non-provisional patent application claims priority under 35 U.S.C. §119 of Korean Patent Application No. 10-2008-0130956, filed on Dec. 22, 2008, the entire contents of which are hereby incorporated by reference.

### BACKGROUND OF THE INVENTION

The present invention disclosed herein relates to a semiconductor device and a method of forming the same, and more particularly, to a non-volatile memory device and a method of forming the same.

Generally, examples of semiconductor devices widely used include a dynamic random access memory (DRAM), a static random access memory (SRAM), and a flash memory. These semiconductor memory devices may be divided into a volatile memory device and a non-volatile memory device. The volatile memory device is a memory device that loses data stored in a memory cell when not powered. Examples of volatile memory devices include DRAM and SRAM. Unlike this, the non-volatile memory device is a memory device that retains data stored in the memory cell even when not powered. Examples of non-volatile memory devices include the flash memory.

In order to maintain data without a power supply, the non-volatile memory device, e.g., the flash memory is widely used to store data for a digital camera, a MP3 player, and a mobile phone. However, because the flash memory accumulates charges in a floating gate under high electric field, the flash memory may have a complicated structure that serves as an obstacle to achieve high integration. Accordingly, a ferroelectric RAM (FRAM), a magnetic RAM (MRAM), a phase-change RAM (PRAM), and a resistive RAM (RRAM) have been proposed as a new next generation semiconductor memory device. In the RRAM, Resistance is varied according to a program voltage applied to an upper electrode and a lower electrode. Data can be stored or deleted according to the variation of the resistance.

### SUMMARY OF THE INVENTION

The present invention provides a non-volatile memory device capable of uniformly maintaining the on/off current ratio by preventing the diffusion of a charge trap even though a switching cycle is repeated.

However, the present invention does not be limited thereto, and also may be clearly understood by a person skilled in the art from the following descriptions.

Embodiments of the present invention provide non-volatile memory devices including: a substrate; a lower electrode on the substrate; a diffusion barrier preventing the diffusion of a space charge on the lower electrode; a charge storage layer having a space charge limited characteristic on the diffusion barrier; and an upper electrode on the charge storage layer.

In other embodiments of the present invention, methods of forming a non-volatile memory device include: forming a lower electrode on a substrate; forming a diffusion barrier on the lower electrode to prevent a diffusion of a space charge; forming a charge storage layer having space charge limited characteristic on the diffusion barrier; and forming an upper electrode on the charge storage layer.

### BRIEF DESCRIPTION OF THE FIGURES

The accompanying figures are included to provide a further understanding of the present invention, and are incorporated in and constitute a part of this specification. The drawings illustrate exemplary embodiments of the present invention and, together with the description, serve to explain principles of the present invention. In the figures:

FIG. 1 is a cross-sectional view illustrating a non-volatile memory device according to an embodiment of the present invention;

FIG. 2 is a graph illustrating the data retention characteristics in the on/off state of a non-volatile memory device without a diffusion barrier;

FIG. 3 is a graph illustrating the log I-V characteristics of a non-volatile memory device according to an embodiment of the present invention;

FIG. 4 is a graph illustrating the data retention characteristics in the on/off state of a non-volatile memory device according to an embodiment of the present invention;

FIGS. 5 through 8 are cross-sectional views illustrating a method of forming a non-volatile memory device according to an embodiment of the present invention; and

FIG. 9 is a block diagram illustrating a memory system including a non-volatile memory device according to an embodiment of the present invention.

### DETAILED DESCRIPTION OF PREFERRED EMBODIMENTS

The advantages, features and aspects of the present invention will become apparent from the following description of the embodiments with reference to the accompanying drawings, which is set forth hereinafter. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Like reference numerals refer to like elements throughout.

In the specification, it will be understood that when a material layer (or film) such as a conductive layer, a semiconductor layer, and an insulating layer is referred to as being ‘on’ another layer or substrate, the material layer can be directly on the other layer or substrate, or an intervening layer may also be present therebetween. Also, though terms like a first, a second, and a third are used to describe various material layers and processing steps in various embodiments of the present invention, the layers and process steps should not be construed limited to these terms. These terms are used only to discriminate a specific layer or processing step from another layer or processing step.

As used herein, the singular forms “a,” “an” and “the” are intended to include the plural forms as well, unless the context clearly indicates otherwise. It will be further understood that the terms “comprises (includes)” and/or “comprising (including),” when used in this specification, specify the presence of stated features, integers, steps, operations, elements, and/or components, but do not preclude the presence or addition of one or more other features, integers, steps, operations, elements, components, and/or groups thereof.

Additionally, the embodiment in the detailed description will be described with reference to sectional views and/or plan views as ideal exemplary views of the present invention. In the figures, the dimensions of layers and regions are exaggerated for clarity of illustration. Accordingly, shapes of the exemplary views may be modified according to manufacturing techniques and/or allowable errors. Therefore, the embodiments of the present invention are not limited to the specific shape illustrated in the exemplary views, but may include other shapes that may be created according to manufacturing processes. For example, an etching region illustrated as angular may have a round shape or a certain curvature. Therefore, regions exemplified in the drawings have general properties, and are used to illustrate a specific shape of a device region. Thus, this should not be construed as limiting the scope of the present invention.

Hereinafter, an exemplary embodiment of the present invention will be described with the accompanying drawings.

Hereinafter, a variable resistance memory device and a method of forming the same according to embodiments of the present invention will be described in detail with reference to the accompanying drawings.

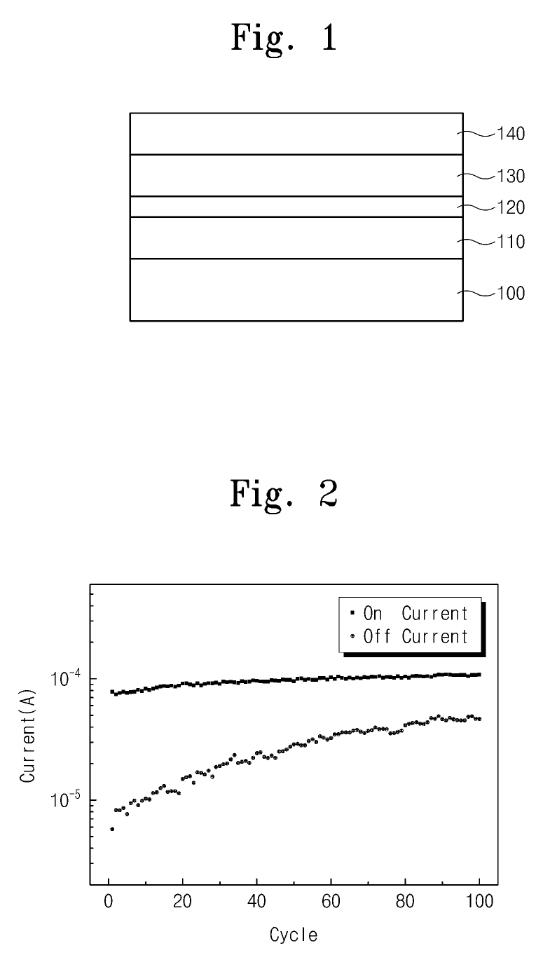

FIG. 1 is a cross-sectional view illustrating a non-volatile memory device according to an embodiment of the present invention.

Referring to FIG. 1, a substrate 100, a lower electrode 110 on the substrate 100, a diffusion barrier 120 on the lower electrode 110, a charge storage layer 130 on the diffusion barrier 120, and an upper electrode 140 on the charge storage layer 130 are provided. The diffusion barrier 120 may prevent a charge trap formed in the charge storage layer 130, i.e., a space charge from being diffused into the lower electrode 110. However, the diffusion barrier 120 must be enough thin so as not to restrict a tunneling. The diffusion barrier 120 according to an embodiment may have a thickness of from about 1 to about 10 nm. The diffusion barrier 120 may be dielectric layer. The dielectric constant of the diffusion barrier 120 may be from about 3 to about 10. The diffusion barrier 120 may be, e.g., an aluminium oxide or a silicon oxide.

The charge storage layer 130 is disposed on the diffusion barrier 120. The charge storage layer 130 has the switching resist characteristics. The charge storage layer 130 may include at least one of materials having a titanium oxide, a zirconium oxide, a hafnium oxide, a vanadium oxide, a niobium oxide, a tantalum oxide, a nickel oxide, a lead oxide, an ABO₃ type dielectric, and a perovskite structure except ABO₃ type. The ABO₃ type dielectric may include LiNbO₃ and CaTiO₃. An impurity element may be added to the charge storage layer 130. The impurity element may be at least one of Ti, V, Cr, Mn, Fe, Co, Ni, Cu, Zn, Zr, Hf, Nb, Ta, Pd, and La. The charge storage layer 130 may form a charge trap, i.e., a space charge through an oxidation-reduction reaction with the upper electrode 140 or the impurity element. Accordingly, the charge storage layer 130 may represent the characteristics of a non-volatile memory that can be mutually switched to high resistance state (off) and low resistance state (on) according to the distribution of the space charge using the space charge limited current (SCLC). The SCLC may be controlled by the impurity element.

The data retention characteristics in the on/off state of a non-volatile memory device without a diffusion barrier are described with reference to FIG. 2. In this comparative example, the lower electrode 110 and the upper electrode 140 may be formed of Al, and the charge storage layer 130 may be formed TiO₂. It can be appreciated that, without diffusion barrier 120, the on/off current ratio is significantly decreased because of the diffusion of the charge trap due to the repetition of the on/off switching cycle.

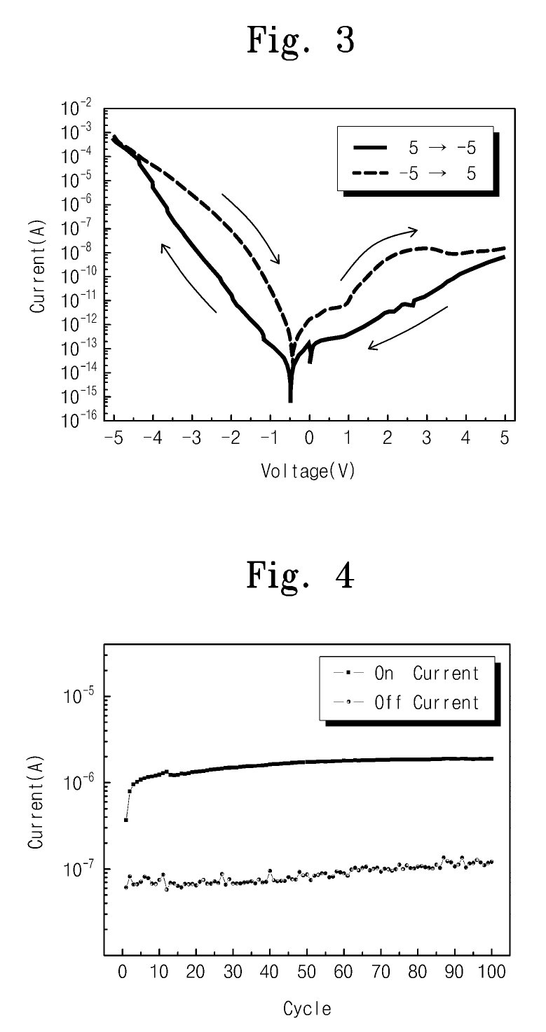

FIGS. 3 and 4 are graphs illustrating the switching characteristics of a non-volatile memory device according to an embodiment of the present invention. In this embodiment, the lower electrode 110 is formed of Au, the diffusion barrier 120 is formed of Al₂O₃, the charge storage layer 130 is formed of TiO₂, and the upper electrode 140 is formed of Al. The thickness of the diffusion barrier 120 is about 3 nm, and the thickness of the charge storage layer 130 is about 10 nm.

The log I-V characteristics of a non-volatile memory device according to an embodiment of the present invention will be described with reference to FIG. 3. If a negative voltage of Vₒₙ˜−5 V is applied to the upper electrode 140 in the off-state of the non-volatile memory device, the non-volatile memory device is switched to the on-state. If a positive voltage of V_{off}˜+5 V is applied to the upper electrode 140 in the on-state, the non-volatile memory device is again switched to the off-state. This process may be repeated, and the on/off states may be maintained without an application of voltage, showing the non-volatile characteristic. The on switching voltage Vₒₙ and off switching voltage V_{off} may be regulated by changing the thicknesses of the charge storage layer 130 and diffusion barrier 120.

The data retention characteristics in the on/off state of a non-volatile memory device according to an embodiment of the present invention will be described with reference to FIG. 4. As described in FIG. 4, the on/off current ratio may be uniformly maintained in spite of the repetition of the on/off cycle by providing the diffusion barrier 120. On the contrary, in the comparative example as described in FIG. 2, it can be appreciated that, without diffusion barrier 120, the on/off current ratio is significantly decreased because of the diffusion of the charge trap due to the repetition of the on/off switching cycle.

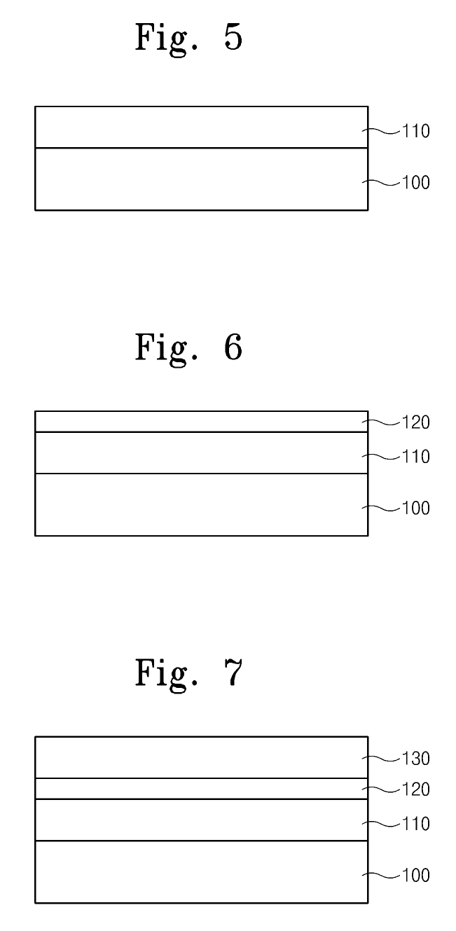

FIGS. 5 through 8 are cross-sectional views illustrating a method of forming a non-volatile memory device according to an embodiment of the present invention.

Referring to FIG. 5, the lower electrode 110 is formed on the substrate 100. The substrate 100 may include any semiconductor-based structure having a silicon surface. Such a semiconductor-based structure may denote silicon, silicon on insulator (SOI), or silicon epitaxial layer supported by the semiconductor structure. The lower electrode 110 may be formed of at least one of a transition metal, a conductive transition metal nitride, and a conductive ternary nitride. According to an embodiment of the present invention, the lower electrode 110 may be form of Au. The lower electrode 110 may be formed through physical vapor deposition (PVD).

Referring to FIG. 6, the diffusion barrier 120 is formed on the lower electrode 110. According to an embodiment of the present invention, the thickness of the diffusion barrier 120 may range from about 1 nm to about 10 nm. The diffusion barrier 120 may be a dielectric layer. The dielectric constant of the diffusion barrier 120 may be from about 3 to about 10. The diffusion barrier 120 may be, e.g., aluminum oxide or silicon oxide. The diffusion barrier 120 may be formed through atomic layer deposition (ALD).

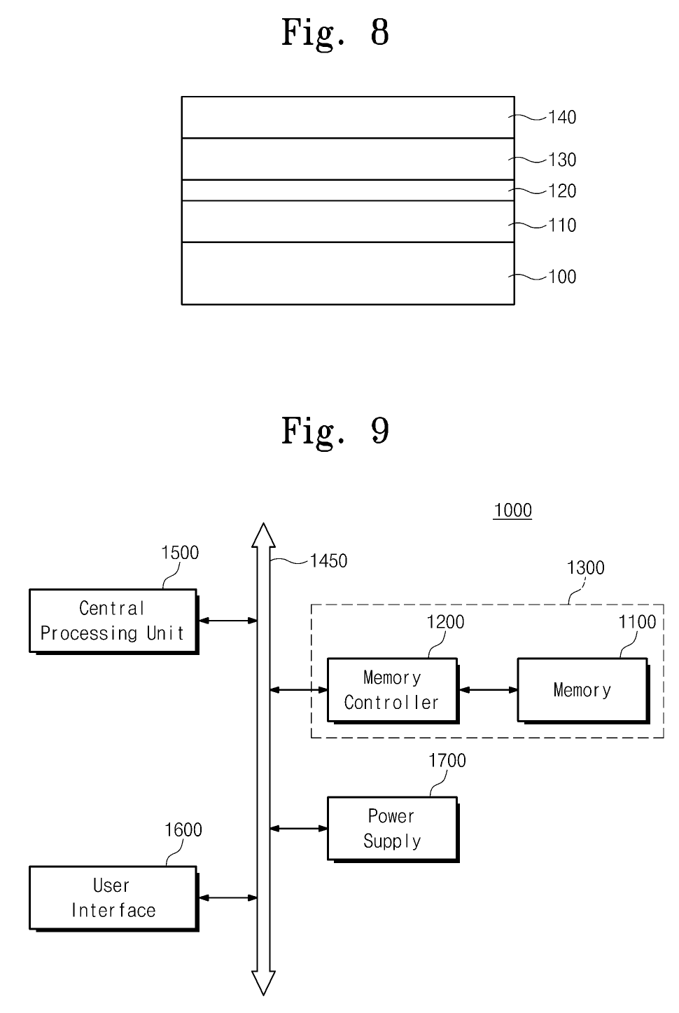

Referring to FIG. 7, charge storage layer 130 is formed on the diffusion barrier 120. The charge storage layer 130 may be formed through sputtering, evaporation, ALD, or chemical vapor deposition (CVD). The charge storage layer 130 may include at least one of titanium oxide, zirconium oxide, hafnium oxide, vanadium oxide, niobium oxide, tantalum oxide, nickel oxide, lead oxide, ABO₃ type dielectric, and material having perovskite structure except ABO₃ type. The charge storage layer may further include an impurity element. The impurity element may be also added as a target material upon sputtering, added as an evaporation material upon evaporation, or added through ion implantation. The impurity element may include at least one of Ti, V, Cr, Mn, Fe, Co, Ni, Cu, Zn, Zr, Hf, Nb, Ta, Pd, and La. Referring to FIG. 8, the upper electrode 140 is formed on the charge storage layer 130. The upper electrode 140 may be formed of the same material as the lower electrode 110. According to an embodiment of the present invention, the upper electrode 140 may be formed of Al.

FIG. 9 is a block diagram illustrating a memory system including a variable resistance memory device according to an embodiment of the present invention.

Referring to FIG. 9, a memory system 1000 includes a semiconductor memory device 1300 including a non-volatile memory device (e.g., RRAM) 1100 and a memory controller 1200, a central processing unit 1500 electrically connected to a system bus 1450, a user interface 1600, and a power supply 1700.

Data provided from the user interface 1600 or processed by the central processing unit 1500 are stored in the non-volatile memory device 1100 via the memory controller 1200. The non-volatile memory device 1100 may include a semiconductor disk device (SSD), which may significantly increase the write speed of the memory system 1000.

Although not shown in the drawings, it will be understood by those skilled in the art that the memory system 1000 according to the embodiment of the present invention may further include an application chipset, a camera image processor (CIS), and a mobile DRAM.

Also, the memory system 1000 can be applied to a device such as a PDA, a potable computer, a web table, a wireless phone, a mobile phone, a digital music player, and a memory card, and all devices capable of transmitting and/or receiving information in a wireless environment.

In addition, the non-volatile memory device or memory system according to the embodiment of the present invention can be mounted in various package forms. For example, the non-volatile memory device or memory system can be packaged in a manner such as package on package (PoP), ball grid arrays (BGAs), chip scale packages (CSPs), plastic leaded chip carrier (PLCC), plastic dual in-line package (PDIP), die in waffle pack, die in wafer form, chip on board (COB), ceramic dual in-line package (CERDIP), plastic metric quad flat pack (MQFP), thin quad flatpack (TQFP), small outline integrated circuit (SOIC), shrink small out line package (SSOP), thin small out line package (TSOP), thin quad flatpack (TQFP), system in package (SIP), multi chip package (MCP), wafer-level fabricated package (WFP), wafer-level processed stack package (WSP).

According to the embodiment of the present invention, a non-volatile memory device having excellent retention characteristic can be provided by using the diffusion barrier.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A non-volatile memory device comprising:
a substrate;
a lower electrode on the substrate;
a diffusion barrier preventing the diffusion of a space charge on the lower electrode;
a charge storage layer having a space charge limited characteristic on the diffusion barrier; and
an upper electrode on the charge storage layer.

2. The non-volatile memory device of claim 1, wherein the diffusion barrier is formed of aluminum oxide or silicon oxide.

3. The non-volatile memory device of claim 1, wherein the thickness of the diffusion barrier ranges from about 1 nm to about 10 nm.

4. The non-volatile memory device of claim 1, wherein the dielectric constant of the diffusion barrier ranges from about 3 to about 10.

5. The non-volatile memory device of claim 1, wherein the charge storage layer comprises at least one of titanium oxide, zirconium oxide, hafnium oxide, vanadium oxide, niobium oxide, tantalum oxide, nickel oxide, lead oxide, ABO₃ type dielectric, and material having perovskite structure except ABO₃ type.

6. The non-volatile memory device of claim 5, wherein the charge storage layer further comprises an impurity element.

7. The non-volatile memory device of claim 6, wherein the impurity element comprises at least one of Ti, V, Cr, Mn, Fe, Co, Ni, Cu, Zn, Zr, Hf, Nb, Ta, Pd, and La.

8. A method of forming a non-volatile memory device, comprising:
forming a lower electrode on a substrate;
forming a diffusion barrier on the lower electrode to prevent a diffusion of a space charge;
forming a charge storage layer having space charge limited characteristic on the diffusion barrier; and
forming an upper electrode on the charge storage layer.

9. The method of claim 8, further comprising adding an impurity element to the charge storage layer.

10. The method of claim 9, wherein the adding of the impurity element is performed by at least one of sputtering, evaporation, and ion implantation.
